(19) United States
(12) Patent Application Publication
(10) Pub. No.: US 2025/0223226 A1
(43) Pub. Date: Jul. 10, 2025

(54) HYDRAULICALLY CURABLE INORGANIC CEMENT COMPOSITION

(71) Applicant: HERAEUS ELECTRONICS GMBH & CO. KG, Hanau (DE)

(72) Inventors: Markus SCHEIBEL, Hanau (DE); Tamara ALBERT, Hanau (DE)

(21) Appl. No.: 18/847,062

(22) PCT Filed: Mar. 14, 2023
(86) PCT No.: PCT/EP2023/056429

§ 371 Date: Sep. 13, 2024

(30) Foreign Application Priority Data
Mar. 18, 2022 (EP) 22162852.2

(51) Int. Cl. C04B 24/26; C04B 24/12; C04B 28/34; C04B 103/00; H01L 21/56

(52) U.S. Cl. CPC C04B 24/2623; C04B 24/128; C04B 28/34; H01L 21/56; C04B 2103/0054

(57) ABSTRACT

Hydraulically curable inorganic cement composition comprising at least one compound with a water solubility of >10 g/L (at 20° C.), selected from the group consisting of 5-member compounds which have an aromatic nitrogenous heterocyclic ring system that is free of other ring heterocyclic atoms and 6-member compounds which have an aromatic nitrogenous heterocyclic ring system that is free of other ring heteroatoms, and at least one water-dispersible EVA copolymer.

The invention relates to a hydraulically curable inorganic cement composition from which an aqueous hydraulically curable inorganic cement preparation can be produced by mixing it with water. The aqueous hydraulically curable inorganic cement preparation can be used to produce a hydraulically cured inorganic cement composition, in particular in the form of an encapsulation of an electronic component.

The term “hydraulic curing” as used herein covers setting in the presence of water or after the addition of water.

A distinction is made herein between a hydraulically curable inorganic cement composition, an aqueous hydraulically curable inorganic cement preparation, and a hydraulically cured inorganic cement composition. An aqueous hydraulically curable inorganic cement preparation, in particular in the form of a viscoelastic, for example pasty or flowable mass, also referred to as “cement paste” or “cement glue”, can be produced from a hydraulically curable inorganic cement composition by mixing it with water. An aqueous hydraulically curable inorganic cement preparation can in turn cure and dry after its application to form a hydraulically cured inorganic cement composition in the form of a hard solid. Said hard solid is also called “cement stone”. A hydraulically cured inorganic cement composition of this kind is practically insoluble in water, i.e. substantially or completely insoluble in water.

The term “electronic component” as used herein covers, in addition to passive electronic components, in particular semiconductor modules, and of these electronic assemblies in particular.

Semiconductor modules are understood herein to mean electronic assemblies comprising at least one substrate (in the form of a circuit carrier), at least one semiconductor unit (semiconductor) and, where applicable, at least one passive electronic component. The at least one semiconductor unit can itself already be partially or completely pre-encapsulated, for example with an epoxy-resin-based sheath.

The term “electronic assembly” is used herein. An electronic assembly within the meaning of the present invention comprises at least one substrate and at least one electronic component mechanically and electrically connected thereto. The mechanical and electrical connection can be an electrically conductive soldered, sintered, and/or adhesive connection. Furthermore, an electronic assembly of this kind can comprise elements providing an electrical connection, such as bonding strips, bonding wires, clips, spacers, and/or foils. Examples of framed or frameless electronic assemblies include discrete components such as power discretes, power modules, voltage converters, and certain sensors.

Examples of substrates include IMS substrates (insulated metal substrates), metal ceramic substrates such as AMB substrates (active metal brazed substrates) and DCB substrates (direct copper bonded substrates), ceramic substrates, PCBs (printed circuit boards), and lead frames.

Electronic components can be divided into active and passive electronic components.

Examples of active electronic components include diodes, LEDs (light-emitting diodes), dies (semiconductor chips), IGBTs (insulated-gate bipolar transistors), ICs (integrated circuits), and MOSFETs (metal-oxide-semiconductor field-effect transistors).

Examples of passive electronic components include base plates, heat sinks, connectors, resistors, capacitors, inductors, antennas, transformers, chokes, coils, and sensors that do not constitute electronic assemblies.

The object of the invention has been to provide a hydraulically curable inorganic cement composition from which aqueous cement encapsulation compounds can be produced for the production of encapsulations of electronic components. The finished encapsulations should be characterized by good adhesion to surfaces of a wide variety of materials, such as those that may be present on electronic components, in particular on a single electronic component. Examples of such diverse material surfaces include surfaces made of ceramics, plastics, semiconductors such as silicon, silicon carbide, and gallium nitride, and metals such as copper, silver, nickel, gold, palladium, and aluminum.

Hydraulically curable inorganic cement compositions are disclosed, for example, in WO 2015/067441 A1, WO 2015/193035 A1, and WO 2019/025033 A1.

It has been found that the object can be achieved by providing a hydraulically curable inorganic cement composition comprising at least one water-soluble compound selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms, and at least one water-dispersible EVA copolymer (ethylene-vinyl acetate copolymer).

The invention specifically relates to a hydraulically curable inorganic cement composition, comprising 0.1 to 10 wt. %, preferably 0.5 to 3 wt. %, of at least one compound with a water solubility>10 g/L (at 20° C.), selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms, and 0.1 to 10 wt. %, preferably 0.5 to 3 wt. %, of at least one water-dispersible EVA copolymer.

For the sake of brevity, the “compound with a water solubility>10 g/L (at 20° C.), selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms” is also referred to as “compound A” in the following.

Preferably, the at least one compound A is present in a weight ratio of 0.8 to 3 to the at least one water-dispersible EVA copolymer.

The hydraulically curable inorganic cement composition according to the invention, which is present as powder (in powder form), can be converted into an aqueous hydraulically curable preparation which can be used as an encapsulation compound by mixing it with water. The aqueous encapsulation compound can be used to produce a hydraulically cured encapsulation of an electronic component.

The hydraulically curable inorganic cement composition according to the invention comprises, in addition to said at least one compound A and said at least one water-dispersible EVA copolymer, possible particulate filler and possible further constituents, a hydraulically curable inorganic cement. Said cement is a powder. The cement powder particles can, for example, have absolute particle sizes in the range of up to 1 mm. The hydraulically curable inorganic cement can, for example, be a Portland cement, aluminous cement, magnesium oxide cement, or phosphate cement known to a person skilled in the art. A phosphate cement is preferred, for example zinc phosphate cement or in particular magnesium phosphate cement. The hydraulically curable inorganic cement can, for example, make up 2 to 95 wt. %, preferably 3 to 40 wt. %, of the hydraulically curable inorganic cement composition according to the invention.

The at least one compound A preferably has at least one polar group, for example an ionic or amphoteric group. The 5-member or 6-member aromatic nitrogenous heterocyclic ring system that is free of other ring heteroatoms can be, for example, a pyrrole, a pyrazole, an imidazole, a triazole, a tetrazole, a pyridine, a pyrimidine, a pyridazine, a pyrazine, or a triazine. This can also be a fused ring system. The at least one compound A can therefore be selected from the group consisting of corresponding derivatives of pyrrole, pyrazole, imidazole, a triazole, tetrazole, pyridine, pyrimidine, pyridazine, pyrazine, or a triazine. Imidazole derivatives are preferred. An imidazole derivative that is particularly preferably used in the hydraulically curable inorganic cement composition according to the invention is the amino acid histidine.

It is assumed that the aromatic nitrogenous heterocyclic ring of the at least one compound A has an in particular adhesion-promoting effect on metal surfaces; a complexing mechanism toward metals such as copper, silver and aluminum is presumed here. The at least one polar group that is preferably present can contribute to the water solubility in the aqueous hydraulically curable inorganic cement preparation. It is further assumed that the at least one polar group that is preferably present in the hydraulically cured inorganic cement composition can orient itself toward the more likely polar cement matrix, while the nitrogenous heterocyclic structure can orient itself toward a metal surface in a presumably complexing manner.

Said water-dispersible EVA copolymers can be produced by emulsion polymerization in an aqueous environment without the addition of organic solvents followed by spray drying. In particular, water-redispersible EVA copolymer dispersion powders can be obtained in this process. Water-redispersible EVA copolymer dispersion powders of this kind having a minimum film-forming temperature, for example in the range of 0 to 4° C., are preferred. Water-redispersible EVA copolymer dispersion powders are commercially available; they are sold, for example, by Wacker under the name VINNAPAS® as an additive for dry mortar, among other things.

The hydraulically curable inorganic cement composition according to the invention can in particular be composed of the following constituents:
(a) 2 to 95 wt. %, preferably 3 to 40 wt. %, of a cement selected from the group consisting of Portland cement, aluminous cement, magnesium oxide cement, and phosphate cement,
(b) 0.1 to 10 wt. %, preferably 0.5 to 3 wt. %, of at least one compound A,
(c) 0.1 to 10 wt. %, preferably 0.5 to 3 wt. %, of at least one water-dispersible EVA copolymer,
(d) 0 to 90 wt. %, preferably 40 to 80 wt. %, of at least one particulate filler, and
(e) 0 to 30 wt. %, preferably 2 to 15 wt. %, of at least one constituent other than constituents (a) to (d). The constituents (a) to (e) add up to 100 wt. % of the hydraulically curable inorganic cement composition according to the invention; in other words, the hydraulically curable inorganic cement composition according to the invention can consist of the constituents (a), (b) and (c) or of the constituents (a), (b), (c) and (d) or of the constituents (a), (b), (c) and (e) or of the constituents (a), (b), (c), (d) and (e).

Constituent (a) is a hydraulically curable inorganic cement. It is a powder. The cement powder particles can, for example, have absolute particle sizes in the range of up to 1 mm. The hydraulically curable inorganic cement is selected from the group consisting of Portland cement, aluminous cement, magnesium oxide cement, and phosphate cement. Constituent (a) is preferably a phosphate cement, for example zinc phosphate cement or in particular magnesium phosphate cement.

The phosphate cement particularly preferred as constituent (a) can be composed of:
(a1) 10 to 90 wt. %, preferably 30 to 60 wt. %, of at least one hydrogen phosphate selected from the group consisting of mono- and dihydrogen phosphates of magnesium, calcium, and aluminum, and
(a2) 90 to 10 wt. %, preferably 70 to 40 wt. %, of at least one compound selected from the group consisting of oxides, hydroxides and oxide hydrates of magnesium, calcium, iron, zinc, zirconium, lanthanum, and copper. The sum of the weight percentage of constituents (a1) and (a2) is 100 wt. % of constituent (a).

Constituent (a1) is at least one substance selected from the group consisting of magnesium monohydrogen phosphate, calcium monohydrogen phosphate, aluminum monohydrogen phosphate, magnesium dihydrogen phosphate, calcium dihydrogen phosphate, and aluminum dihydrogen phosphate. In other words, it is at least one hydrogen phosphate selected from the group consisting of mono- and dihydrogen phosphates of magnesium, calcium, and aluminum. In particular, it is at least one hydrogen phosphate selected from the group consisting of mono- and dihydrogen phosphates of magnesium and aluminum.

Constituent (a1) is a powder having absolute particle sizes in the range of up to 1 mm, for example.

Constituent (a2) is at least one compound selected from the group consisting of oxides, hydroxides and oxide hydrates of magnesium, calcium, iron, zinc, zirconium, lanthanum, and copper, in particular at least one compound selected from the group consisting of magnesium oxide, magnesium hydroxide, zirconium oxide, zirconium oxide hydrate, and zirconium hydroxide. Magnesium oxide is particularly preferred.

Constituent (a2) is a powder having absolute particle sizes in the range of up to 1 mm, for example.

For the sake of brevity, with regard to constituents (b) and (c) reference is made to the aforementioned.

The optional, but preferably present, constituent (d) is at least one particulate filler, which can in particular be selected from the group consisting of mono-, oligo- and polyphosphates of magnesium, calcium, barium, and aluminum; calcium sulfate; barium sulfate; simple and complex silicates comprising calcium, aluminum, magnesium, iron, and/or zirconium; simple and complex aluminates comprising calcium, magnesium, and/or zirconium; simple and complex titanates comprising calcium, aluminum, magnesium, barium, and/or zirconium; simple and complex zirconates comprising calcium, aluminum, and/or magnesium; zirconium dioxide; titanium dioxide; aluminum oxide; silicon dioxide, in particular in the form of silica and quartz; silicon carbide; aluminum nitride; boron nitride and silicon nitride. A distinction is made herein between simple and complex silicates, aluminates, titanates, and zirconates. The complex representatives are not, for example, complex compounds but rather silicates, aluminates, titanates, and zirconates having more than one type of cation, such as calcium aluminum silicate, lead zirconium titanate, etc.

Constituent (d) is a powder having absolute particle sizes in the range of up to 1 mm, for example.

The optional constituent (e) is one or more constituents that are in each case different from constituents (a) to (d), such as flow improvers, setting retarders (pot-life extenders), defoamers, hydrophobizing agents, surface-tension-influencing additives, wetting agents, adhesion promoters, and fibers. Examples of fibers include glass fibers, basalt fibers, boron fibers, and ceramic fibers, for example silicon carbide fibers and aluminum oxide fibers, rock wool fibers, wollastonite fibers, and aramid fibers.

The hydraulically curable inorganic cement composition according to the invention that in particular consists of the constituents (a), (b), (c), preferably also (d) and optionally (e) can be present in the form of a one-component powdered composition or in the form of two or more powdered components, i.e. different and separate components (components that are to be stored separately or are stored separately). In the case of a two-component or multi-component composition, the components together comprise all the constituents, i.e. in particular constituents (a), (b) and (c); or (a) to (d); (a) to (e); or (a), (b), (c) and (e). The two or more components are stored separately from one another until they are used to produce an aqueous hydraulically curable inorganic cement preparation; in this case, it may be particularly expedient to store constituents (a1) and (a2) at least substantially separately from one another.

An aqueous hydraulically curable inorganic cement preparation can be produced from a hydraulically curable inorganic cement composition according to the invention, which can be in one-component, two-component, or multi-component powder form, by mixing it with water. In the case of a two-component or multi-component system, the components can first be mixed to form a one-component hydraulically curable inorganic cement composition and then mixed with water. However, it is also possible to first mix only one, some or all of the components with water, for example to form pastes; further mixing can then take place to form the aqueous hydraulically curable inorganic cement preparation. An aqueous hydraulically curable inorganic cement preparation of this kind can be used to produce a hydraulically cured inorganic cement composition, in particular in the form of an encapsulation of an electronic component; after its application, it can cure and dry hydraulically to form a hydraulically cured inorganic cement composition in the form of a hard solid. Said hard solid can in particular be said encapsulation of an electronic component.

An aqueous hydraulically curable inorganic cement preparation obtainable from a hydraulically curable inorganic cement composition according to the invention by mixing it with water can have a water content of 6 to 25 wt. %, for example.

The viscosity of a freshly produced (within 5 minutes of completion) aqueous hydraulically curable inorganic cement preparation can, for example, be in the range of 0.5 to 20 Pa·s (when determined by rotational viscometry, plate-plate measuring principle, plate diameter 25 mm, measuring gap 1 mm, sample temperature 20° C.).

As mentioned, the aqueous hydraulically curable inorganic cement preparation can be used as an aqueous encapsulation compound for electronic components. For the sake of brevity, the term “aqueous encapsulation compound” will also be used in the following instead of “aqueous hydraulically curable inorganic cement preparation”.

The aqueous encapsulation compound can be used to produce a hydraulically cured encapsulation of electronic components. The production method includes the steps of:
(1) providing an electronic component to be encapsulated,
(2) providing an aqueous encapsulation compound produced by mixing a hydraulically curable inorganic cement composition according to the invention with water,
(3) encapsulating the electronic component provided in step (1) with the aqueous encapsulation compound provided in step (2), and
(4) hydraulically curing the aqueous encapsulation compound encapsulating the electronic component after completion of step (3).

In step (1), an electronic component to be encapsulated is provided. With regard to the term “electronic component”, reference is made to the aforementioned.

With regard to step (2), reference is made to the aforementioned.

Preferably, step (3) is carried out immediately, for example within 60 minutes, preferably within 10 minutes, of completion of step (2) or after completion of the production of the aqueous encapsulation compound.

In step (3), the electronic component provided in step (1) is encapsulated with the aqueous encapsulation compound provided in accordance with step (2). Preferred application methods are casting, dipping, and injection molding. Casting can be carried out using conventional methods known to a person skilled in the art, for example by gravity-assisted, vacuum-assisted, or pressure-assisted casting (compression molding). In this case, it may be expedient to enclose the electronic component to be encapsulated in half-shell molds and then fill them with the aqueous encapsulation compound. The encapsulation can be partial or complete encapsulation. For example, when encapsulating a semiconductor module, the encapsulation compound can partially or completely encapsulate electrical contacting elements connected to the semiconductor unit, such as bonding wires, strips, and/or a substrate. Partial encapsulation means that one or more of the contacting elements is encapsulated in an incomplete manner and/or one or more of the contacting elements is/are not encapsulated, while complete encapsulation means that all the contacting elements are completely encapsulated. However, the casting can, for example, also be carried out such that the encapsulation compound is formed as a “glob top”, which is known to a person skilled in the art.

In step (4), which follows step (3), the aqueous encapsulation compound encapsulating the electronic component is hydraulically cured. Of course, the hydraulic curing begins as soon as the aqueous encapsulation compound has been produced, i.e. during or after completion of step (2).

The hydraulic curing can take place under ambient conditions, for example at an ambient temperature in the range of 20 to 25° C., and can take 1 minute to 6 hours, for example. If the duration is to be shortened, work can be carried out at higher temperatures; for example, the hydraulic curing can take place at object temperatures of 30 to under 100° C. and is then completed within a few seconds to 2 hours, for example.

Hydraulic curing is expediently followed by drying of the encapsulation for the purpose of removing chemically unbound water from the hydraulically cured inorganic cement composition. This can be done at a later time; however, the hydraulic curing can expediently also be followed by forced drying for dewatering, for example for 0.5 to 6 hours at an object temperature of 80 to 200° C.; it may be expedient to go through several temperature stages. This drying can take place with vacuum assistance.

### COMPARATIVE EXAMPLES V1 TO V3 AND EXAMPLES 1 TO 4 ACCORDING TO THE INVENTION

7 parts by weight of magnesium oxide powder, 2 parts by weight of magnesium dihydrogen phosphate powder, and 76 parts by weight of zirconium silicate powder having a maximum particle size of 100 μm were premixed to form a hydraulically curable inorganic magnesium phosphate cement composition. The premix was then mixed with histidine, a water-redispersible EVA copolymer dispersion powder (VINNAPAS® 5044N from Wacker) and water in accordance with the parts by weight in table 1 to form aqueous hydraulically curable magnesium phosphate cement preparations.

TABLE 1

| | | | EVA | Weight ratio of | |
|---|---|---|---|---|---|
| | Premix | Histidine | copolymer | histidine to EVA | Water |
| Example | (wt. %) | (wt. %) | (wt. %) | copolymer | (wt. %) |
| V1 | 85 | 0 | 1.16 | — | 13.84 |
| V2 | 85 | 2.12 | 0 | — | 12.88 |
| V3 | 85 | 0 | 0 | — | 15.00 |
| 1 | 85 | 1.16 | 1.16 | 1.00 | 12.68 |
| 2 | 85 | 0.34 | 2.01 | 0.17 | 12.65 |
| 3 | 85 | 0.75 | 1.50 | 0.50 | 12.75 |
| 4 | 85 | 2.12 | 0.42 | 5.00 | 12.46 |

The adhesion of the aqueous hydraulically curable magnesium phosphate cement preparations after application and hydraulic curing to copper and aluminum oxide surfaces was determined as follows:

Silicone masks having six square cut-outs of 5×5 cm each were placed on flat copper or aluminum-oxide ceramic plates. The aqueous hydraulically curable magnesium phosphate cement preparation in question was introduced into the cut-outs using a syringe up to a fill level of 3 mm. The cement preparation was then hydraulically cured at 20° C. for 2 hours. The silicone masks were then removed and the copper or aluminum oxide ceramic plates provided with the hydraulically cured square cement samples were treated in a laboratory furnace by increasing the furnace temperature from 20° C. to 90° C. at a heating rate of 1° C./min and keeping it at 90° C. for 1 hour. The furnace temperature was then increased to 160° C. at a heating rate of 1° C./min and kept at 160° C. for 1 hour. The plates were then cooled to 20° C. at a rate of 1° C./min. The shear strength was then determined six-fold using the DAGE 2000 measuring device from the company Dage (Germany). The cement samples were sheared using a shear chisel having an edge length of 6 mm at a shear height of ⅔ of the sample height while maintaining a shear rate of 300 μm/s. To improve the measurement accuracy, the shear force of the 100 kg load cell was reduced to 20 kg. Table 2 shows the measurement results obtained.

TABLE 2

| | Adhesion to copper | Adhesion to aluminum oxide |
|---|---|---|
| Example | (MPa) | (MPa) |
| V1 | 0 (no adhesion) | 0.6 |
| V2 | 1.0 | 0 (no adhesion) |
| V3 | 0 (no adhesion) | 0 (no adhesion) |
| 1 | 2.5 | 1.4 |
| 2 | 0.3 | 0.1 |
| 3 | 1.4 | 0.3 |
| 4 | 1.1 | 0.1 |

1. A hydraulically curable inorganic cement composition comprising at least one water-soluble compound selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms, and at least one water-dispersible EVA copolymer.

2. The hydraulically curable inorganic cement composition according to claim 1, comprising 0.1 to 10 wt. % of at least one compound with a water solubility>10 g/L (at 20° C.), selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms, and 0.1 to 10 wt. % of at least one water-dispersible EVA copolymer.

3. The hydraulically curable inorganic cement composition according to claim 2, wherein the at least one compound with a water solubility>10 g/L (at 20° C.) selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms is present in a weight ratio of 0.8 to 3 to the at least one water-dispersible EVA copolymer.

4. The hydraulically curable inorganic cement composition according to claim 2, comprising a hydraulically curable inorganic cement in addition to the at least one compound with a water solubility>10 g/L (at 20° C.) selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms, the at least one water-dispersible EVA copolymer, possible particulate filler, and possible further constituents.

5. The hydraulically curable inorganic cement composition according to claim 4, wherein the hydraulically curable inorganic cement is a Portland cement, aluminous cement, magnesium oxide cement, or phosphate cement.

6. The hydraulically curable inorganic cement composition according to claim 4, wherein the hydraulically curable inorganic cement makes up 2 to 95 wt. % of the hydraulically curable inorganic cement composition.

7. A hydraulically curable inorganic cement composition composed of:
(a) 2 to 95 wt. % of a cement selected from the group consisting of Portland cement, aluminous cement, magnesium oxide cement, and phosphate cement,
(b) 0.1 to 10 wt. % of at least one compound with a water solubility>10 g/L (at 20° C.), selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms,
(c) 0.1 to 10 wt. % of at least one water-dispersible EVA copolymer,
(d) 0 to 90 wt. % of at least one particulate filler, and
(e) 0 to 30 wt. % of at least one constituent other than constituents (a) to (d),
wherein constituents (a) to (e) add up to 100 wt. %.

8. The hydraulically curable inorganic cement composition according to claim 7, wherein constituent (a) is a phosphate cement composed of:
(a1) 10 to 90 wt. % of at least one hydrogen phosphate selected from the group consisting of mono- and dihydrogen phosphates of magnesium, calcium, and aluminum, and
(a2) 90 to 10 wt. % of at least one compound selected from the group consisting of oxides, hydroxides and oxide hydrates of magnesium, calcium, iron, zinc, zirconium, lanthanum, and copper,
where the sum of the weight percentage of constituents (a1) and (a2) is 100 wt. %.

9. The hydraulically curable inorganic cement composition according to claim 2, wherein the at least one compound with a water solubility>10 g/L (at 20° C.) selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms is selected from the group consisting of derivatives of pyrrole, pyrazole, imidazole, a triazole, tetrazole, pyridine, pyrimidine, pyridazine, pyrazine, or a triazine.

10. The hydraulically curable inorganic cement composition according to claim 9, wherein the at least one compound with a water solubility>10 g/L (at 20° C.) selected from the group consisting of 5-member compounds which have an aromatic nitrogenous heterocyclic ring system that is free of other ring heteroatoms and 6-member compounds which have an aromatic nitrogenous heterocyclic ring system that is free of other ring heteroatoms is an imidazole derivative.

11. The hydraulically curable inorganic cement composition according to claim 1 in the form of a one-component powdered composition or in the form of two or more different and separate powdered components.

12. An aqueous hydraulically curable inorganic cement preparation produced by mixing a hydraulically curable inorganic cement composition according to claim 1 with water.

13. A use of an aqueous hydraulically curable inorganic cement preparation according to claim 12 for producing a hydraulically cured inorganic cement composition in the form of an encapsulation of an electronic component.

14. A method for producing a hydraulically cured encapsulation of an electronic component, comprising the steps of:
(1) providing an electronic component to be encapsulated,
(2) providing an aqueous encapsulation compound produced by mixing a hydraulically curable inorganic cement composition according to claim 1 with water,
(3) encapsulating the electronic component provided in step (1) with the aqueous encapsulation compound provided in step (2), and
(4) hydraulically curing the aqueous encapsulation compound encapsulating the electronic component after completion of step (3).
